(19) United States
(12) Patent Application Publication
(10) Pub. No.: US 2007/0181950 A1
(43) Pub. Date: Aug. 9, 2007

(54) Semiconductor device and its manufacturing method capable of suppressing junction leakage current

(75) Inventors: Shinichi Miyake, Kanagawa (JP); Takashi Watanabe, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/656,564

(22) Filed: Jan. 23, 2007

(30) Foreign Application Priority Data
Jan. 24, 2006 (JP) 2006-014941

(51) Int. Cl. H01L 29/76; H01L 21/8238

(52) U.S. Cl. 257/371; 438/228; 257/E27.067

(57) ABSTRACT

In a semiconductor device including a semiconductor substrate, a gate insulating layer formed on the semiconductor substrate, a gate electrode layer formed on the gate insulating layer, a source region and a drain region formed within the semiconductor substrate adjacent to the gate electrode layer, and sidewall insulating layers formed on sidewalls of the gate electrode layer and the gate insulating layer, air gaps are formed between one of the sidewall insulating layers and the source region and between another of the sidewall insulating layers and the drain region. Semiconductor layers are formed on the source region and the drain region outside of said air gaps, and upper surfaces of the semiconductor layers are higher than upper surfaces of the air gaps. Silicide layers are formed on the semiconductor layers.

### BACKGROUND OF THE INVENTION

1. Field of the Invention

The present invention relates to a semiconductor device, particularly to a p-channel MOS transistor, and its manufacturing method.

2. Description of the Related Art

As information communication apparatuses have been developed, semiconductor devices therein require higher speed operations.

The high speed operations of semiconductor devices such as metal oxide semiconductor (MOS) transistors can be realized by downsizing them. For example, a gate length and a junction depth of a MOS transistor are made smaller.

Generally, in a MOS transistor, each drain region (source region) is constructed by one lightly-doped impurity diffusion region beneath a sidewall insulating layer and one highly-doped impurity diffusion region adjacent to the lightly-doped impurity diffusion region. This is called a lightly-doped drain (LDD) structure. On the other hand, in order to reduce the contact resistance between the drain region (source region) and its wiring layer, the upper portion of the drain region (source region) is silicified by a salicide process, so that a silicide layer is formed on the drain region (source region).

In the above-mentioned MOS transistor, when the junction depth is smaller, a junction leakage current may be increased which would increase the power consumption. Particularly, a gate induced drain leakage current is caused by a reversely-biased drain-to-gate voltage in the proximity of the lightly-doped impurity diffusion region beneath the sidewall insulating layer. Note that the gate induced drain leakage current is a kind of junction leakage current.

In a prior art semiconductor device (see: FIG. 15 of JP-11-243201-A), in order to reduce the gate induced drain leakage current and the junction leakage current, an air gap is formed between the sidewall silicon insulating layer and the lightly-doped impurity diffusion region, so that the silicide layer of the drain region (source region) is separated from a gate electrode layer by the air gap. This will be explained later in detail.

### SUMMARY OF THE INVENTION

In the above-described prior art semiconductor device, however, the silicide layer extends into the air gap beneath the sidewall insulating layer, so that the reduction of the gate induced drain leakage current and the junction leakage current is insufficient. Particularly, in a 65 nm or more fined technology node, a large gate induced drain leakage current flows therethrough.

According to the present invention, in a semiconductor device including a semiconductor substrate, a gate insulating layer formed on the semiconductor substrate, a gate electrode layer formed on the gate insulating layer, a source region and a drain region formed within the semiconductor substrate adjacent to the gate electrode layer, and sidewall insulating layers formed on sidewalls of the gate electrode layer and the gate insulating layer, air gaps are formed between one of the sidewall insulating layers and the source region and between another of the sidewall insulating layers and the drain region. Semiconductor layers are formed on the source region and the drain region outside of the air gaps, and upper surfaces of the semiconductor layers are higher than upper surfaces of the air gaps. Silicide layers are formed on the semiconductor layers.

Additionally, in a semiconductor device including a p-channel MOS transistor and an n-channel MOS transistor, each of the p-channel MOS transistor and the n-channel MOS transistor includes a gate insulating layer formed on a semiconductor substrate, a gate electrode layer formed on a gate insulating layer, a source region and the drain region formed within the semiconductor substrate adjacent to the gate electrode layer, and sidewall insulating layers of a multi-layer structure of SiO₂ and SiN formed on sidewalls of the gate electrode layer and the gate insulating layer. Also, air gaps are formed between one of the sidewall insulating layers and the source region of the p-channel MOS transistor and between another of the sidewall insulating layers and the drain region of the p-channel MOS transistor, and semiconductor layers are formed on the source region and the drain region of the p-channel MOS transistor outside of the air gaps, upper surfaces of the semiconductor layers being higher than upper surfaces of the air gaps. Further, silicide layers are formed on the semiconductor layers of the p-channel MOS transistor and the source region and the drain region of the n-channel MOS transistor.

### BRIEF DESCRIPTION OF THE DRAWINGS

The present invention will be more clearly understood from the description set forth below, as compared with the prior art, with reference to the accompanying drawings, wherein:

FIG. 1 is a cross-sectional view illustrating a prior art semiconductor device;

FIGS. 2A through 2J are cross-sectional views for explaining a first embodiment of the method for manufacturing a semiconductor device according to the present invention;

FIG. 3 is a diagram for explaining the relationship between the elastic modulus of a sidewall insulating layer and the strain of a channel portion in a MOS transistor;

FIGS. 4A through 4J are cross-sectional views for explaining a second embodiment of the method for manufacturing a semiconductor device according to the present invention;

FIGS. 5A through 5J are cross-sectional views for explaining a third embodiment of the method for manufacturing a semiconductor device according to the present invention; and

FIG. 6 is a cross-sectional view illustrating a modification of the semiconductor device of FIG. 5I.

### DESCRIPTION OF THE PREFERRED EMBODIMENTS

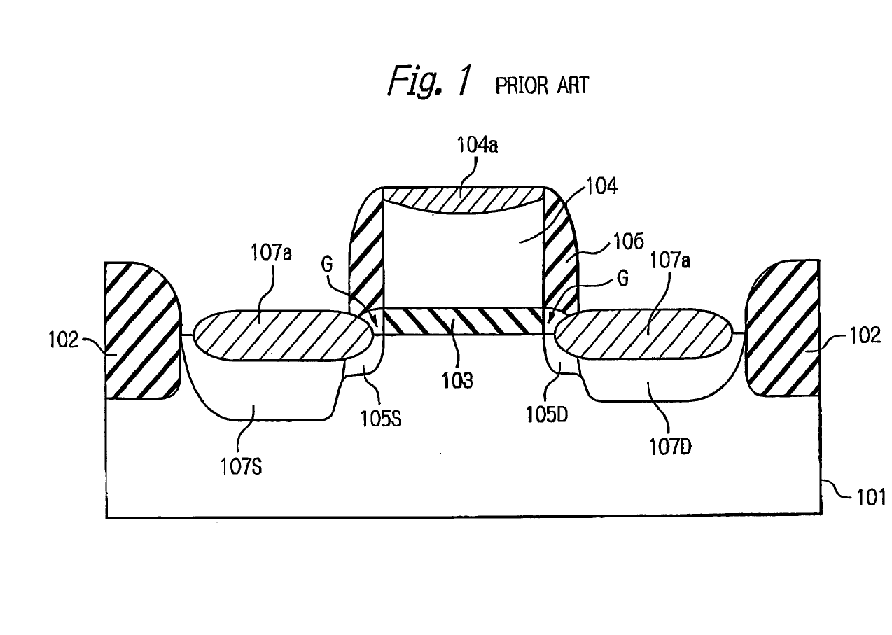

Before the description of the preferred embodiments, a prior art semiconductor device will be explained with reference to FIG. 1 (see: FIG. 15 of JP-11-243201-A).

In FIG. 1, reference numeral 101 designates a monocrystalline silicon substrate where a field silicon oxide layer 102 is formed by a local oxidation of silicon (LOCOS) process to partition a MOS transistor forming area. Also, a gate silicon dioxide layer 103 is grown by thermally oxidizing the silicon substrate 101, and a gate polycrystalline silicon layer 104 is formed on the gate silicon dioxide layer 103 by a chemical vapor deposition (CVD) process. Further, lightly-doped impurity diffusion regions 105S and 105D are formed within the silicon substrate 101 in self-alignment with the gate polycrystalline silicon layer 104. Additionally, sidewall silicon dioxide layers 106 are formed on the sidewalls of the gate polycrystalline silicon layer 104. Still, highly-doped impurity diffusion regions 107S and 107D are formed in self-alignment with the sidewall silicon dioxide layer 106. Note that the lightly-doped impurity diffusion region 105S and the highly-doped impurity diffusion region 107S form a source region, and the lightly-doped impurity diffusion region 105D and the highly-doped impurity diffusion region 107D form a drain region.

On the other hand, in order to reduce the contact resistance between the gate polycrystalline silicon layer 104 and its wiring layer (not shown) and the contact resistance between the source and drain regions and their wiring layers (not shown), the upper portion of the gate polycrystalline silicon layer 104 and the upper portions of the highly-doped impurity diffusion regions 107S and 107D are silicified by a self-aligned silicide (salicide) process, so that silicide layers 104a and 107a are formed on the source region and the drain region, respectively.

In order to reduce the gate induced drain leakage current and the junction leakage current, air gaps G are formed between the lightly-doped impurity diffusion regions 105S and 105D and the sidewall silicon dioxide layers 106, so that the silicide layers 107a are separated from the gate polycrystalline silicon layer 104.

In the semiconductor device of FIG. 1, however, the silicide layers 107a extend into the air gaps G beneath the sidewall silicon dioxide layer 106, so that the reduction of the gate induced drain leakage current and the junction leakage current is insufficient.

Note that as the silicide layers 107a approach the gate polycrystalline silicon layer 104, the gate induced drain leakage current and the junction leakage current are increased.

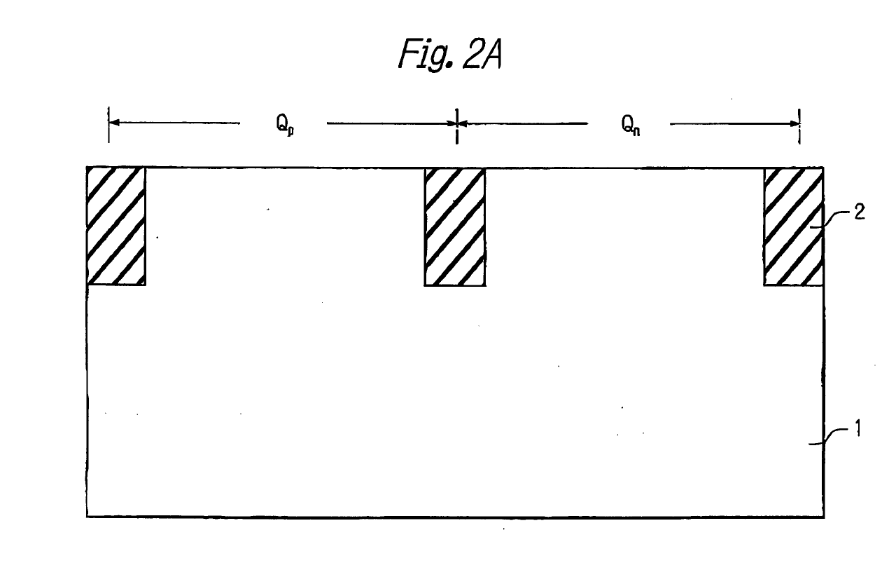

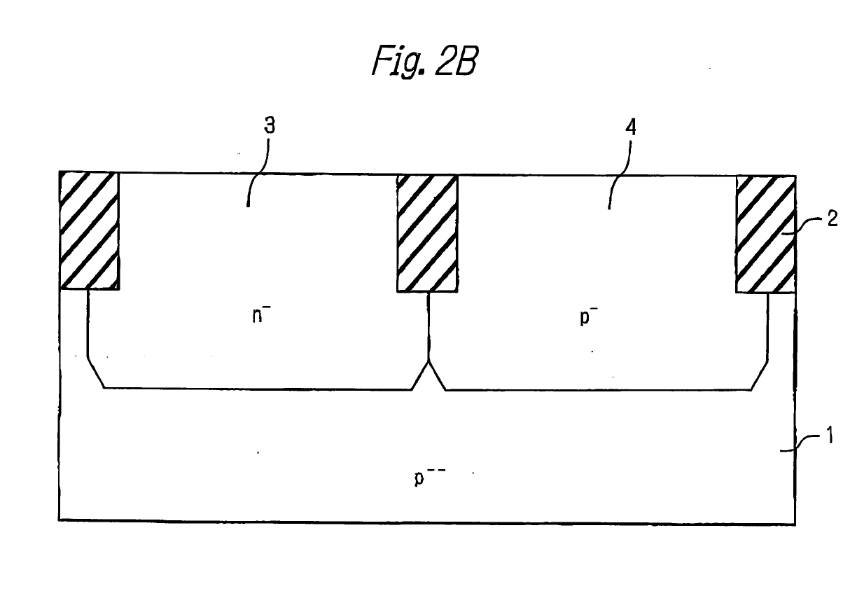

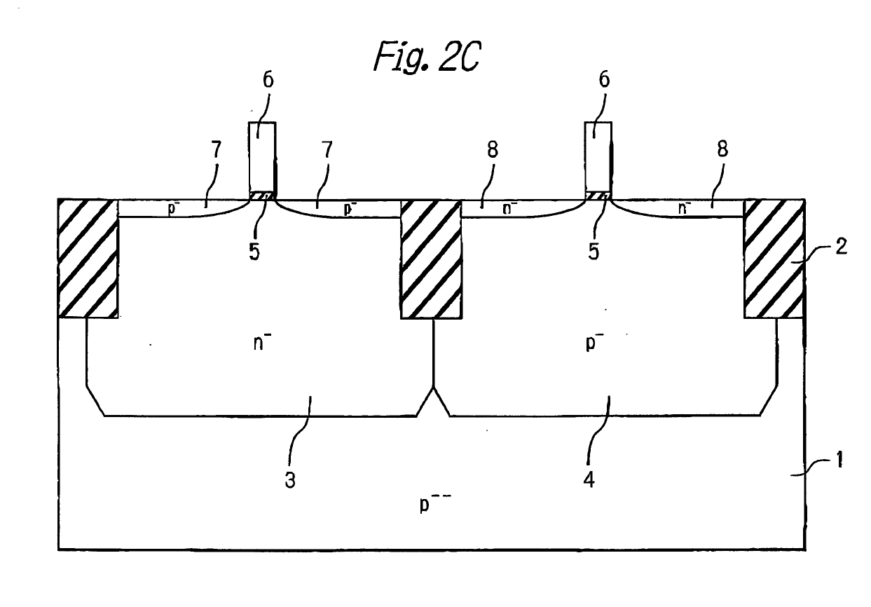

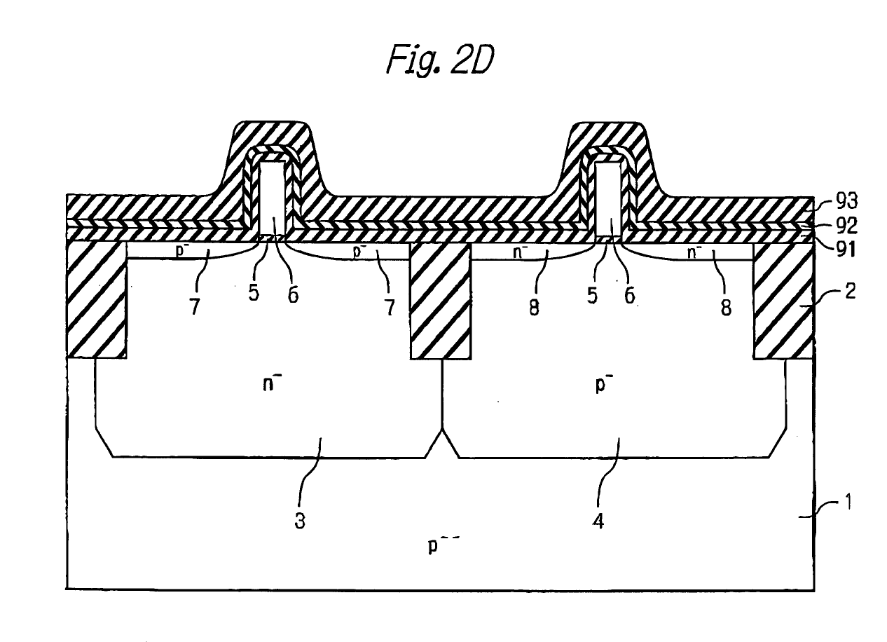

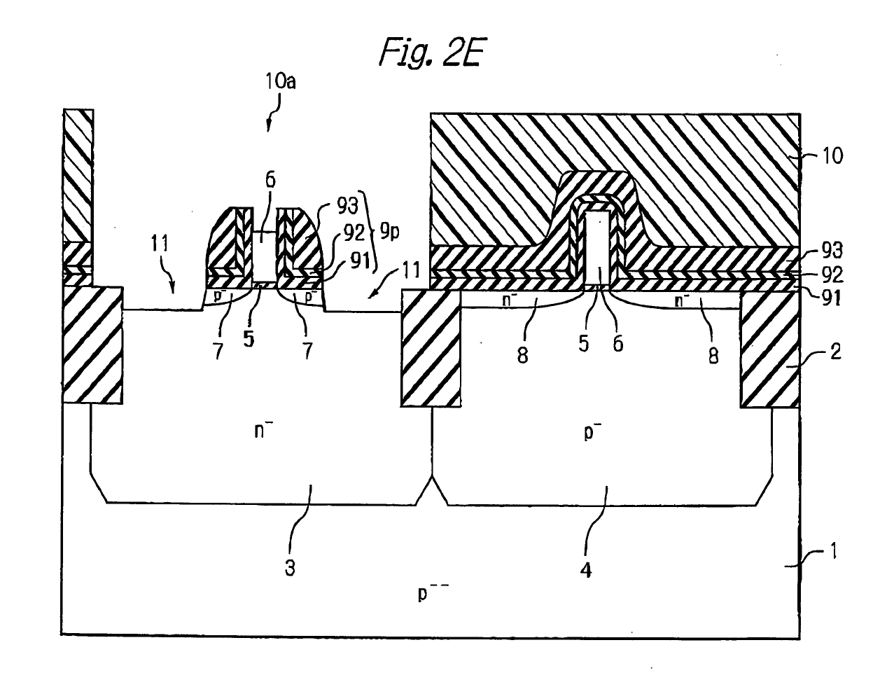

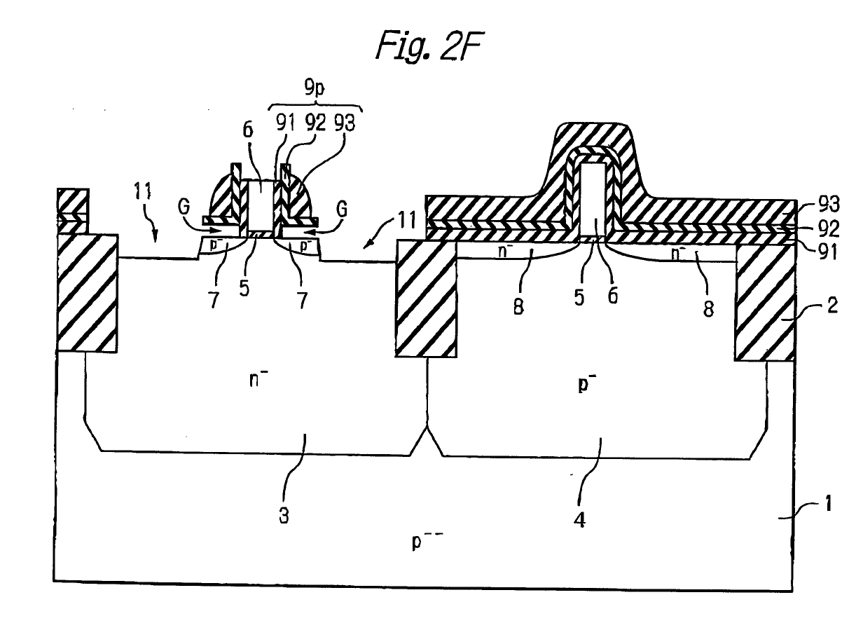

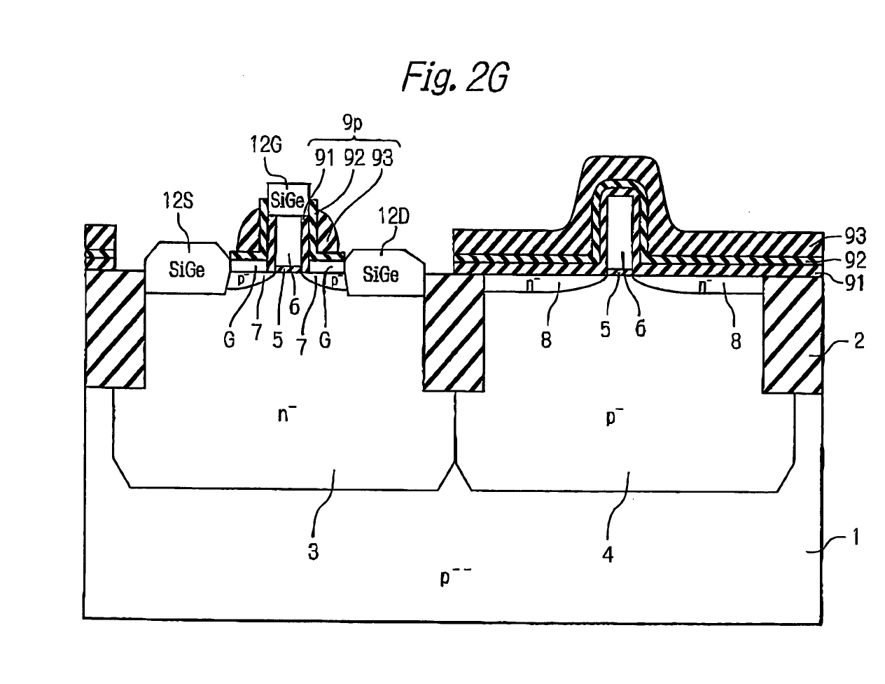

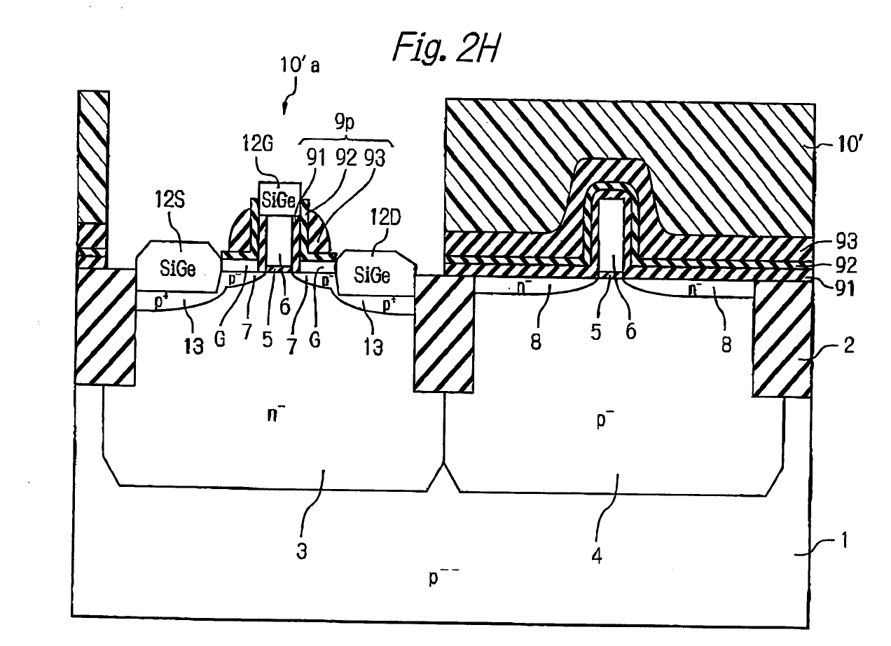

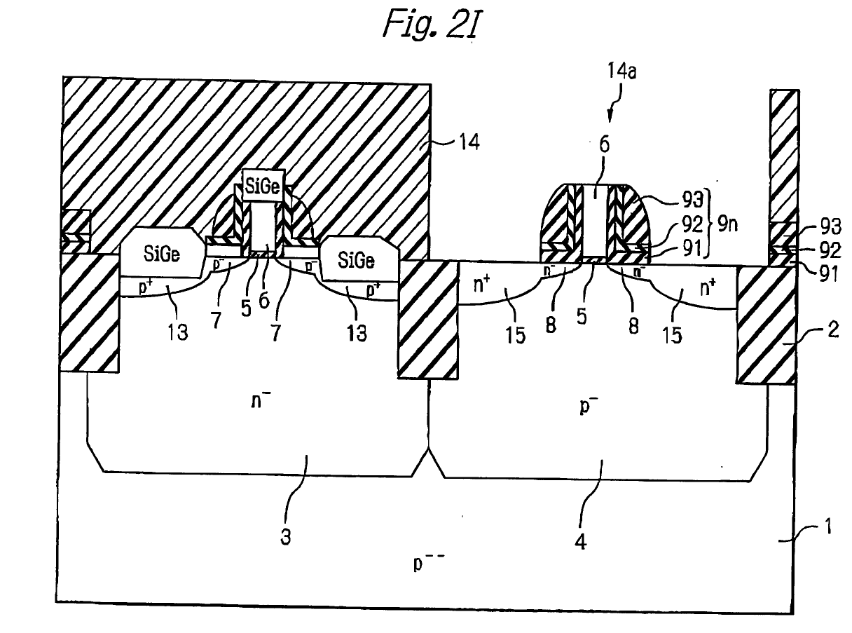

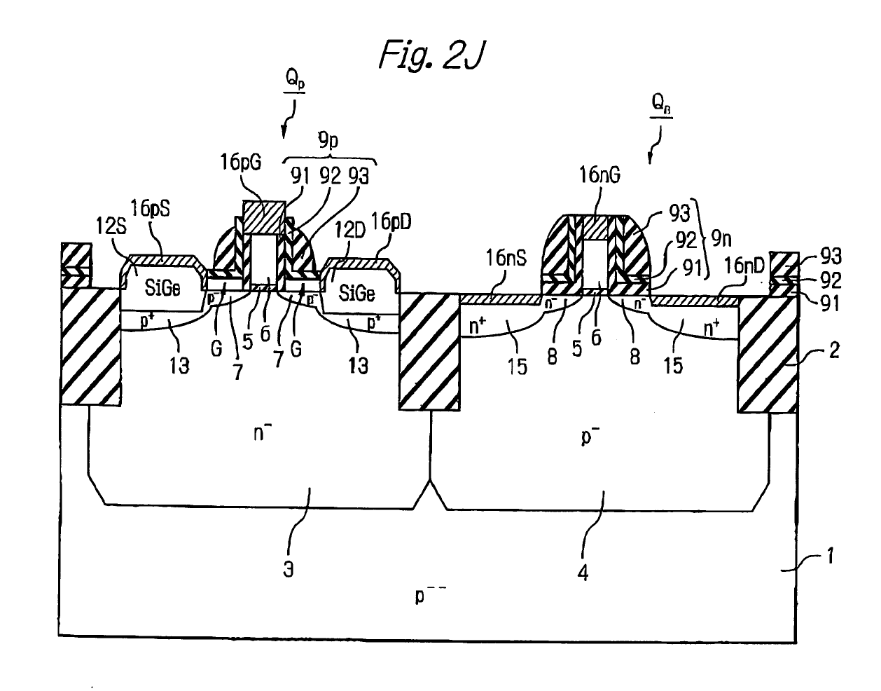

A first embodiment of the method for manufacturing a semiconductor device such as a p-channel MOS transistor Qₚ and an n-channel MOS transistor Qₙ according to the present invention will be explained next with reference to FIGS. 2A through 2J.

First, referring to FIG. 2A, a shallow trench isolation (STI) layer 2 Is formed within a p⁻⁻-type monocrystalline siliconsubstrate 1 to partition areas for the transistors Qₚ and Qₙ from each other.

Next, referring to FIG. 2B, arsenic (or phosphorus) ions are implanted at a relatively-high energy into the silicon substrate 1 by using a photoresist pattern layer (not show) having an opening corresponding to the p-channel MOS transistor Qₚ as a mask, to form an n⁻-type impurity diffusion well 3. Also, boron ions are implanted at a relatively-high energy into the silicon substrate 1 by using a photoresist pattern layer (not shown) having an opening corresponding to the n-channel MOS transistor Qₙ as a mask, to form a p⁻-type impurity diffusion well 4.

Next, referring to FIG. 2C, a gate insulating layer 5 made of silicon dioxide (SiO₂), silicon oxide nitride (SiON), or a high-k material such as HfO₂, HfSiO or HfAlO is formed. Then, a gate electrode layer 6 made of polycrystalline silicon is formed on the gate insulating layer 5. Then, the gate electrode layer 6 and the gate insulating layer 5 are patterned by a photolithography and etching process. Then, boron ions are implanted at a relatively-low energy into the n⁻-type impurity diffusion well 3 by using a photoresist pattern layer (not shown) having an opening corresponding to the p-channel MOS transistor Qₚ as a mask in self-alignment with the gate electrode layer 6, to form p⁻-type impurity diffusion regions 7. Also, arsenic (or phosphorus) ions are implanted at a relatively-low energy into the p⁻-type impurity diffusion well 4 by using a photoresist pattern layer (not shown) having an opening corresponding to the n-channel MOS transistor Qₙ as a mask in self-alignment with the gate electrode layer 6, to form n⁻-type impurity diffusion regions 8.

Next, referring to FIG. 2D, in order to form sidewall insulating layers, a silicon dioxide layer 91, a silicon nitride layer 92 and a silicon dioxide layer 93 are sequentially deposited in this order on the entire surface by a CVD process.

Next, referring to FIG. 2E, a photoresist pattern layer 10 having an opening 10a corresponding to the p-channel MOS transistor Qₚ is formed by a photolithography process. Then, the silicon dioxide layer 93, the silicon nitride layer 92 and the silicon dioxide layer 91 are etched back by an anisotropic dry etching process, to form a sidewall insulating layer 9p. Then, upper portions of the n⁻-type impurity diffusion well 3 are etched by using the sidewall insulating layer 9p as a mask. As a result, about 100 to 1000 Å deep recesses 11 are formed within the n⁻-type impurity diffusion well 3. In this case, the exposed portions of the p⁻-type impurity diffusion regions 7 may be completely etched. Note that, an upper portion of the gate electrode layer 6 is simultaneously etched. Then, the photoresist pattern layer 10 is removed.

Next, referring to FIG. 2F, the silicon dioxide layers 91 and 93 are etched by a wet etching process, so that air gaps G are formed between the silicon nitride layer 92 and the p⁻-type impurity diffusion regions 7.

Next, referring to FIG. 2G, SiGe layers 12G, 12S and 12D are epitaxially grown on the gate electrode layer 6, the source region and the drain region, respectively. In this case, the upper surfaces of the SiGe layers 12S and 12D are higher than those of the air gaps G. Also, it is preferable that the SiGe layers 12S and 12D are as close as possible to the sidewall insulating layer 9p. At best, the SiGe layers 12S and 12D are in contact with the sidewall insulating layer 9p, so that the air gaps G are clogged.

Next, referring to FIG. 2H, a photoresist pattern layer 10′ having an opening 10′a corresponding to the p-channel MOS transistor Qₚ is formed by a photolithography process. Then, boron ions are implanted at a relatively-high energy into the n⁻-type impurity diffusion well 3 by using the photoresist pattern layer 10′ as a mask in self-alignment with the sidewall insulating layer 9p, to form p⁺-type impurity diffusion regions 13. Then, the photoresist pattern layer 10′a is removed.

Next, referring to FIG. 2I, a photoresist pattern layer 14 having an opening 14a corresponding to the n-channel MOS transistor Qₙ is formed by a photolithography process. Then, the silicon dioxide layer 93, the silicon nitride layer 92 and the silicon dioxide layer 91 are etched back by an anisotropic dry etching process, to form a sidewall insulating layer 9n. Then, arsenic (or phosphorus) ions are implanted at a relatively-high energy into the p⁻-type impurity diffusion well 4 by using the photoresist pattern layer 14 as a mask in self-alignment with the sidewall insulating layer 9n, to form n⁺-type impurity diffusion regions 15. Then, the photoresist pattern layer 14 is removed. Then, an annealing operation is performed upon the impurity diffusion regions 7, 8, 13 and 15.

Finally, referring to FIG. 2J, a metal layer (not shown) made of Ti, Pt, Co or Ni is deposited on the entire surface. In this case, since the upper surfaces of the SiGe layers 12S and 12D are above the air gaps G, the metal layer is not deposited within the air gaps G. Then, an annealing process is performed upon the metal layer and its underlying silicon component, so that silicide layers 16pG, 16pS, 16pD, 16nG, 16nS and 16nD made of TiSi₂, PtSi, CoSi₂ or NiSi are formed within the SiGe layer 12G, 12S, 12D, the gate electrode layer 6, the source region and the drain region of the n-channel MOS transistor Qₙ, respectively. Then, unreacted portions of the metal layer are removed by a wet etching process. That is, the silicide layers 16pG, 16pS, 16pD, 16nG, 16nS and 16nD are formed by a salicide process.

Thus, the p-channel MOS transistor Qₚ and the n-channel MOS transistor Qₙ are completed.

In FIG. 2J, since the SiGe layers 12S and 12D completely prevent the silicide layers 16pS and 16pD from extending into the impurity diffusion regions 7 and 13 beneath the air gaps G, the gain induced drain current and the junction leakage current can be suppressed.

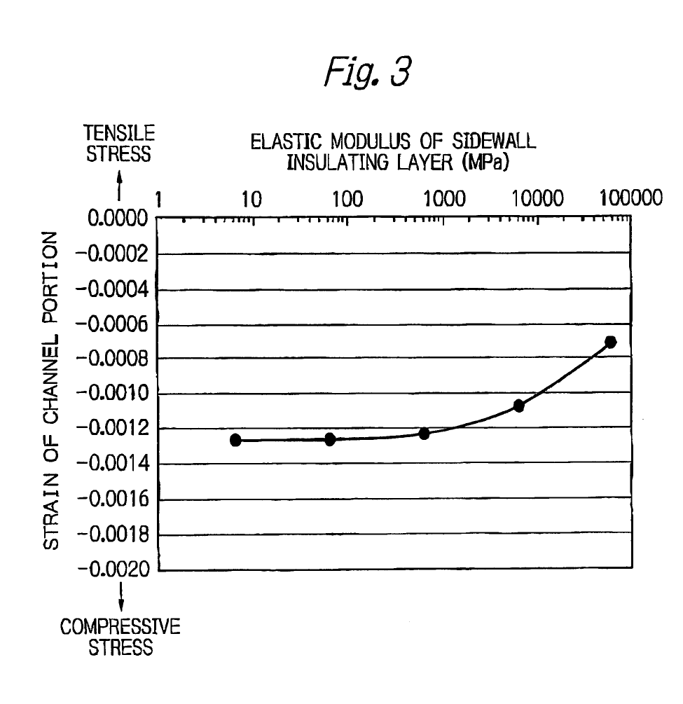

Also, in FIG. 2J, the sidewall insulating layers 9p for the p-channel MOS transistor Qₚ and the sidewall insulating layers 9n for the n-channel MOS transistor Qₙ have similar structures to each other. That is, the sidewall insulating layers 9p and 9n are of a three-layer structure formed by SiO₂/SiN/SiO₂ where the silicon nitride (SiN) layer 92 has an L-shaped cross section. As shown in FIG. 3, if the sidewall insulating layers 9p and 9n are made of only SiN, the elastic modulus of the sidewall insulating layers 9p and 9n is so large that the strains of the channel regions of the transistors Qₚ and Qₙ are on the tensile side. As a result, the electron mobility of the n-channel MOS transistor Qₙ is enhanced while the hole mobility of the p-channel MOS transistor Qₚ is degraded. Therefore, since the sidewall insulating layers 9p is of a three-layer structure formed by SiO₂/SiN/SiO₂, the hole mobility of the p-channel MOS transistor Qₚ may be degraded. In this case, however, since the air gaps G are present only on the side of the p-channel MOS transistor Qₚ, the tensile side strain of the p-channel MOS transistor Qₚ is relaxed, so that the shear modulus of the sidewall insulating layers 9p is substantially decreased to make the strain of the p-channel region of the p-channel MOS transistor Qₚ on the compressive side which would enhance the hole mobility of the p-channel MOS transistor Qₚ. Furthermore, the SiGe layers 12S and 12D generate a compressive stress in the channel region of the p-channel MOS transistor Qₚ to enhance the hole mobility thereof. Thus, the characteristics such as the ON current of the p-channel MOS transistor Qₚ can be improved.

Further, in FIG. 2J, the fringe capacitance of the p-channel MOS transistor Qₚ can be decreased by the air gaps G.

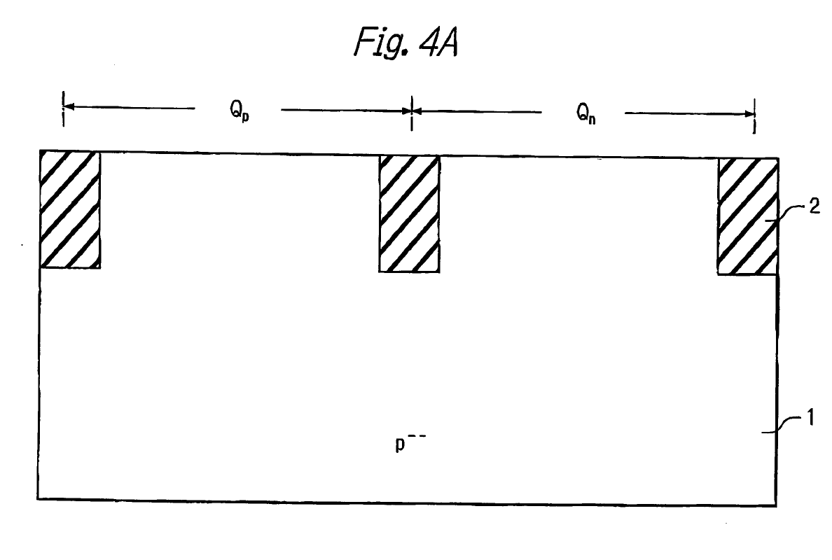

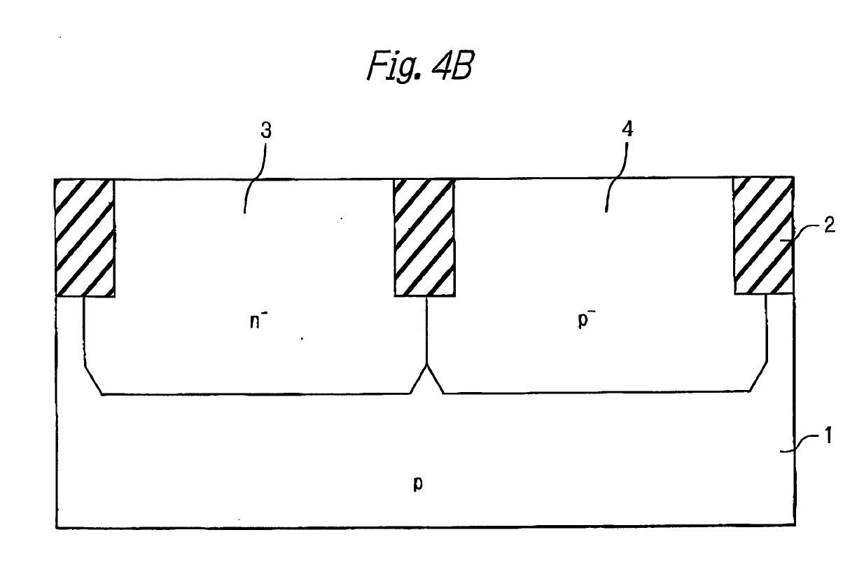

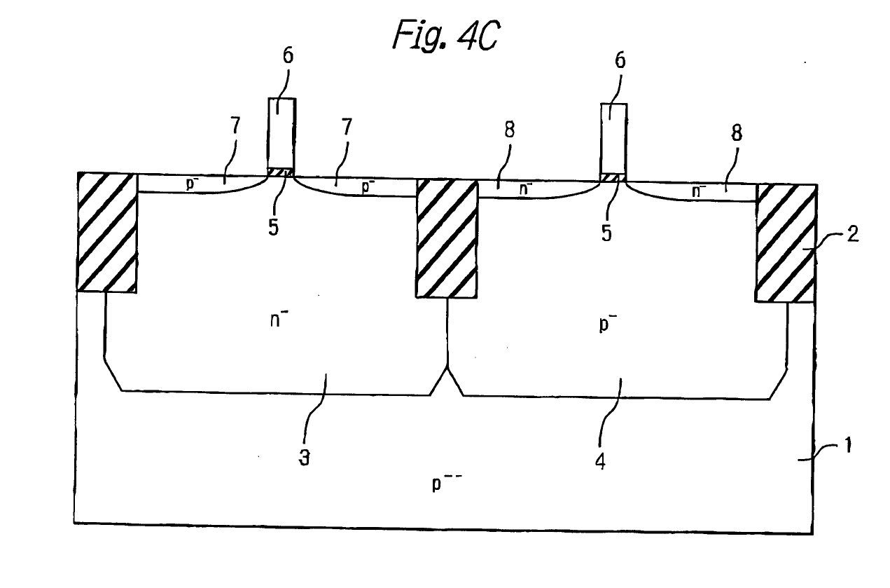

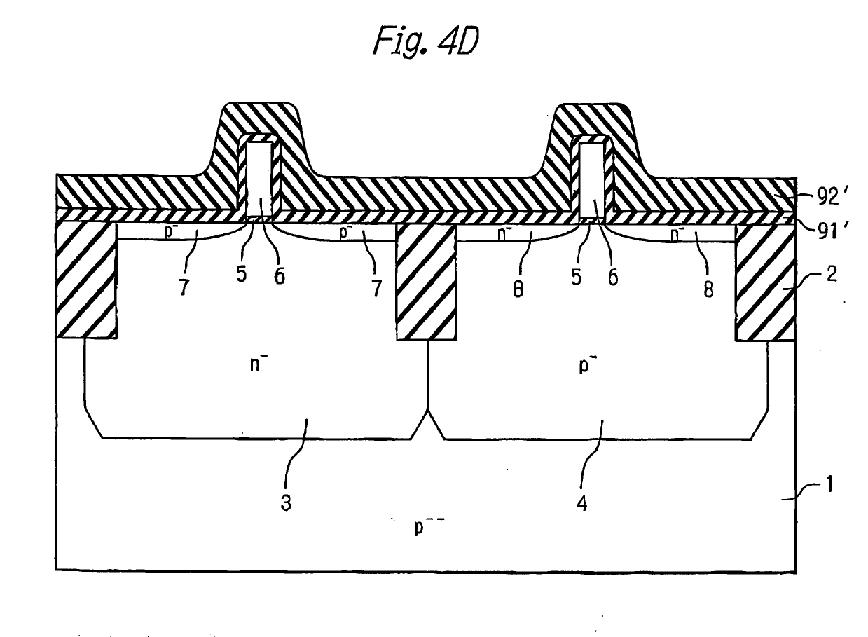

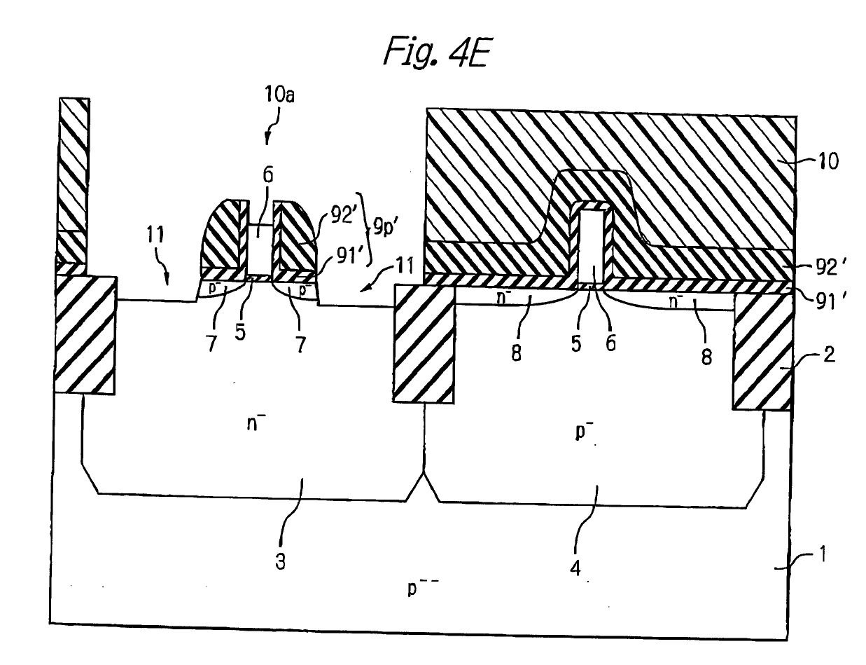

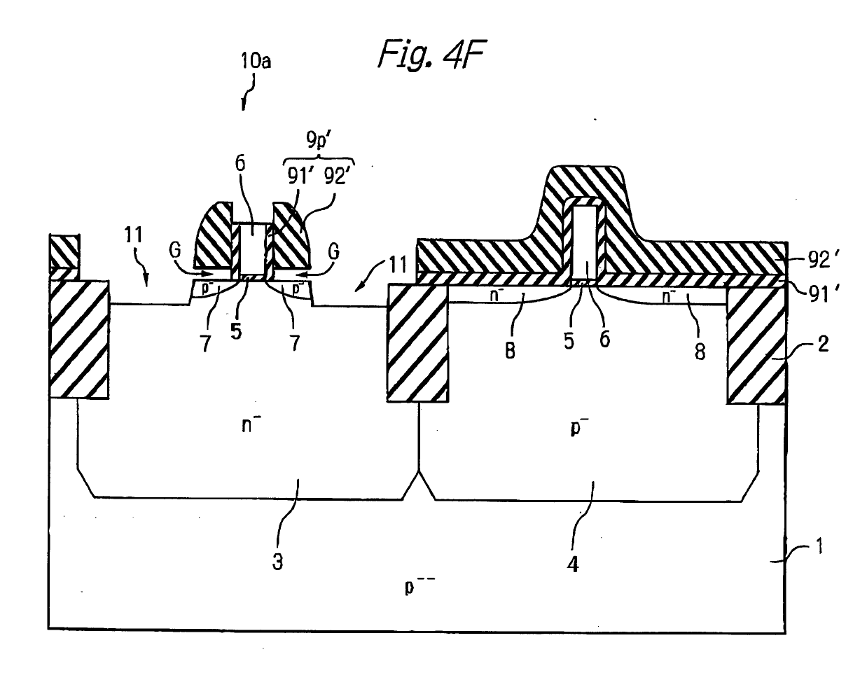

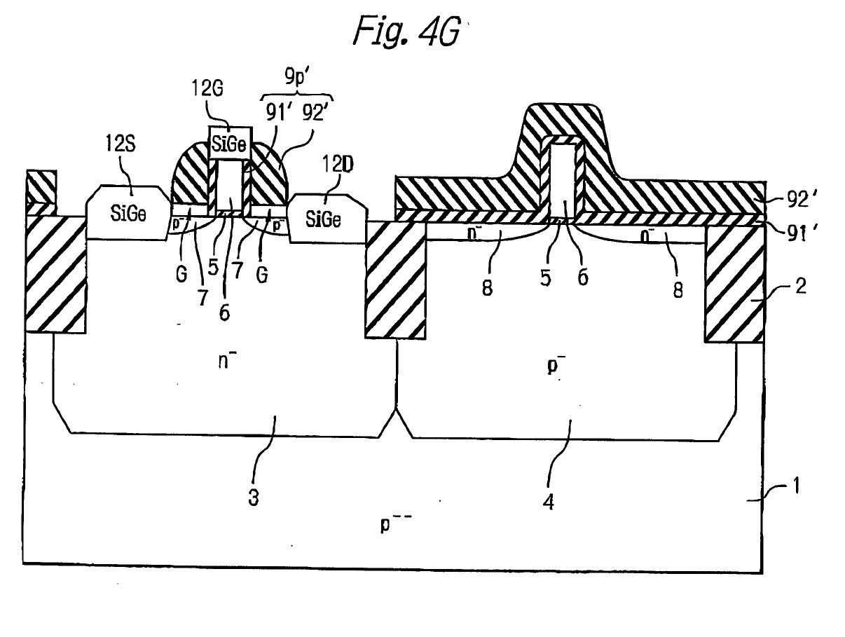

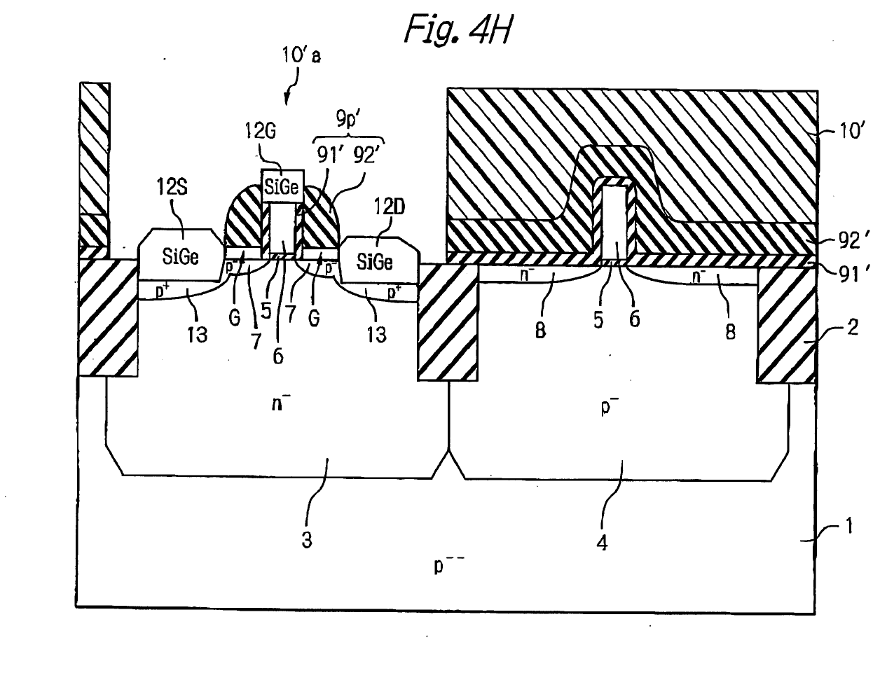

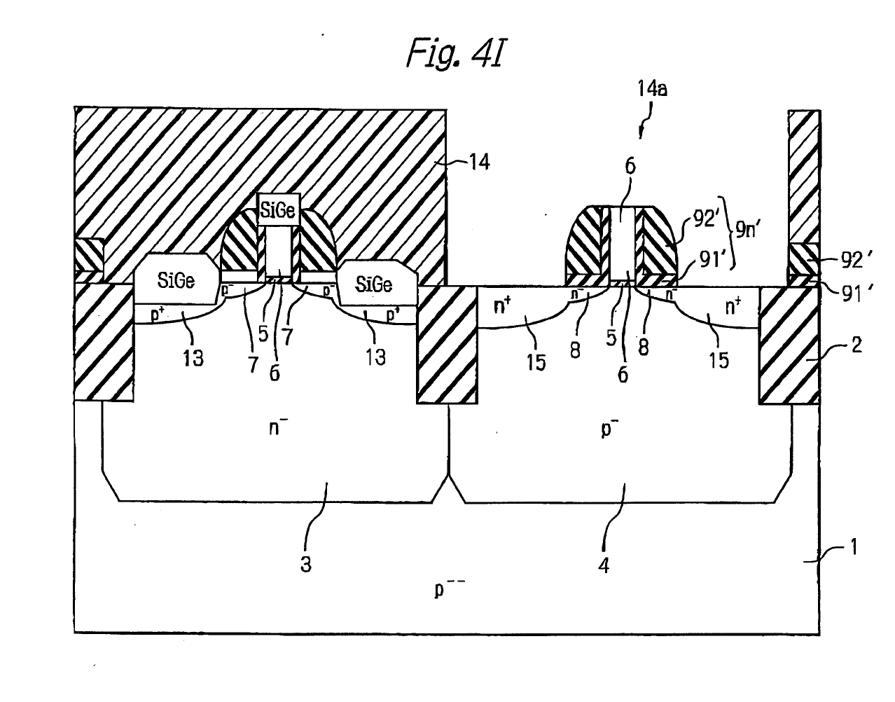

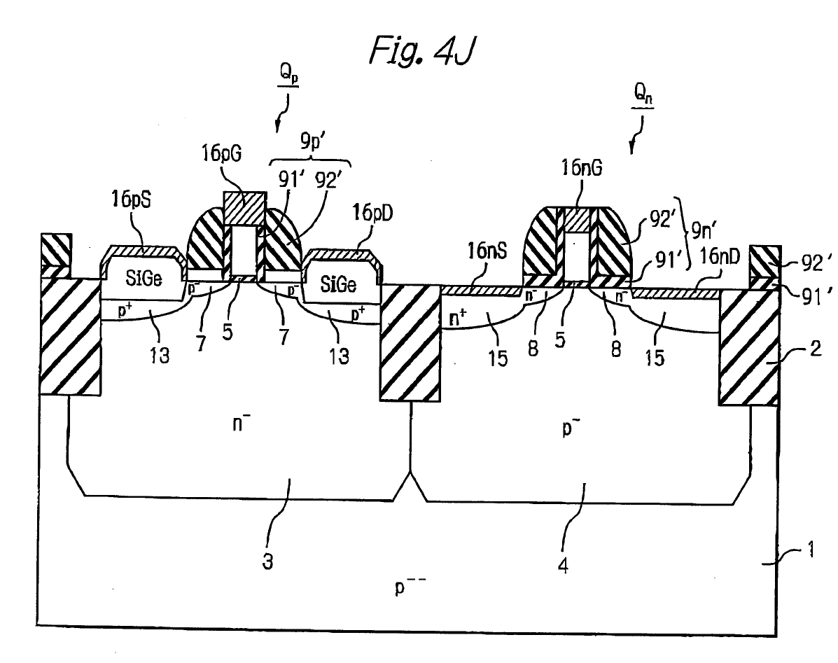

A second embodiment of the method for manufacturing a semiconductor device such as a p-channel MOS transistor Qₚ and an n-channel MOS transistor Qₙ according to the present invention will be explained next with reference to FIGS. 4A through 4J.

First, referring to FIG. 4A, in the same way as in FIG. 2A, an STI layer 2 is formed within a p⁻⁻-type monocrystalline silicon substrate 1 to partition areas for the transistors Qₚ and Qₙ from each other.

Next, referring to FIG. 4B, in the same way as in FIG. 2B, arsenic (or phosphorus) ions are implanted at a relatively-high energy into the silicon substrate 1 by using a photoresist pattern layer (not shown) having an opening corresponding to the p-channel MOS transistor Qₚ as a mask, to form an n⁻-type impurity diffusion well 3. Also, boron ions are implanted at a relatively-high energy into the silicon substrate 1 by using a photoresist pattern layer (not shown) having an opening corresponding to the n-channel MOS transistor Qₙ as a mask, to form a p⁻-type impurity diffusion well 4.

Next, referring to FIG. 4C, in the same way as in FIG. 2C, a gate insulating layer 5 made of silicon dioxide (SiO₂), silicon oxide nitride (SiON), or a high-k material such as HfO₂, HfSiO or HfAlO is formed. Then, a gate electrode layer 6 made of polycrystalline silicon is formed on the gate insulating layer 5. Then, the gate electrode layer 6 and the gate insulating layer 5 are patterned by a photolithography and etching process. Then, boron ions are implanted at a relatively-low energy into the n⁻-type impurity diffusion well 3 by using a photoresist pattern layer (not shown) having an opening corresponding to the p-channel MOS transistor Qₚ as a mask in self-alignment with the gate electrode layer 6, to form p⁻-type impurity diffusion regions 7. Also, arsenic (or phosphorus) ions are implanted at a relatively-low energy into the p⁻-type impurity diffusion well 4 by using a photoresist pattern layer (not shown) having an opening corresponding to the n-channel MOS transistor Qₙ as a mask in self-alignment with the gate electrode layer 6, to form n⁻-type impurity diffusion regions 8.

Next, referring to FIG. 4D, in order to form sidewall insulating layers, a silicon dioxide layer 91′ and a silicon nitride layer 92′ are sequentially deposited in this order on the entire surface by a CVD process.

Next, referring to FIG. 4E, in a similar way to those of FIG. 2E, a photoresist pattern layer 10 having an opening 10a corresponding to the p-channel MOS transistor Qₚ is formed by a photolithography process. Then, the silicon nitride layer 92′ and the silicon dioxide layer 91′ are etched back by an anisotropic dry etching process, to form a sidewall insulating layer 9p′. Then, upper portions of the n⁻-type impurity diffusion well 3 are etched by using the sidewall insulating layer 9p′ as a mask. As a result, about 100 to 1000 Å deep recesses 11 are formed within the n⁻-type impurity diffusion well 3. In this case, the exposed portions of the p⁻-type impurity diffusion regions 7 may be completely etched. Note that, an upper portion of the gate electrode layer 6 is simultaneously etched. Then, the photoresist pattern layer 10 is removed.

Next, referring to FIG. 4F, the silicon dioxide layer 91′ is etched by a wet etching process, so that air gaps G are formed between the silicon nitride layer 92′ and the p⁻-type impurity diffusion regions 7.

Next, referring to FIG. 4G, in the same way as in FIG. 2G, SiGe layers 12G, 12S and 12D are epitaxially grown on the gate electrode layer 6, the source region and the drain region, respectively. In this case, the upper surfaces of the SiGe layers 12S and 12D are higher than those of the air gaps G. Also, it is preferable that the SiGe layers 12S and 12D are as close as possible to the sidewall insulating layer 9p′. At best, the SiGe layers 12S and 12D are in contact with the sidewall insulating layer 9p′, so that the air gaps G are clogged.

Next, referring to FIG. 4H, in the same way as in FIG. 2H, a photoresist pattern layer 10′ having an opening 10′a corresponding to the p-channel MOS transistor Qₚ is formed by a photolithography process. Then, boron ions are implanted at a relatively-high energy into the n⁻-type impurity diffusion well 3 by using the photoresist pattern layer 10′ as a mask in self-alignment with the sidewall insulating layer 9p′, to form p⁺-type impurity diffusion regions 11. Then, the photoresist pattern layer 10′ is removed.

Next, referring to FIG. 4I, in the same way as in FIG. 2I, a photoresist pattern layer 13 having an opening 13a corresponding to the n-channel MOS transistor Qₙ is formed by a photolithography process. Then, the silicon nitride layer 92′ and the silicon dioxide layer 91′ are etched back by an anisotropic dry etching process, to form a sidewall insulating layer 9n′. Then, arsenic (or phosphorus) ions are implanted at a relatively-high energy into the p⁻-type impurity diffusion well 4 by using the photoresist pattern layer 13 as a mask in self-alignment with the sidewall insulating layer 9n′, to form n⁺-type impurity diffusion regions 14. Then, the photoresist pattern layer 13 is removed. Then, an annealing operation is performed upon the impurity diffusion regions 7, 8, 13 and 15.

Finally, referring to FIG. 4J, in a similar way to those of FIG. 2J, a metal layer (not shown) made of Ti, Pt, Co or Ni is deposited on the entire surface. In this case, since the upper surfaces of the SiGe layers 12S and 12D are above the air gaps G, the metal layer is not deposited within the air gaps G. Then, an annealing process is performed upon the metal layer and its underlying silicon component, so that silicide layers 16pG, 16pS, 16pD, 16nG, 16nS and 16nD made of TiSi₂, PtSi, CoSi₂ or NiSi are formed within the SiGe layer 12G, 12S, 12D, the gate electrode layer 6, the source region and the drain region of the n-channel MOS transistor Qₙ, respectively. Then, unreacted portions of the metal layer are removed by a wet etching process. That is, the silicide layers 16pG, 16pS, 16pD, 16nG, 16nS and 16nD are formed by a salicide process.

Thus, the p-channel MOS transistor Qₚ and the n-channel MOS transistor Qₙ are completed.

Even in FIG. 4J, since the SiGe layers 12S and 12D completely prevent the silicide layers 16pS and 16pD from extending into the impurity diffusion regions 7 and 13 beneath the air gaps G, the gain induced drain current and the junction leakage current can be suppressed.

Also, even in FIG. 4J, the sidewall insulating layers 9p′ for the p-channel MOS transistor Qₚ and the sidewall insulating layers 9n′ for the n-channel MOS transistor Qₙ have similar structures to each other. That is, the sidewall insulating layers 9p′ and 9n′ are of a two-layer structure formed by SiO₂/SiN. In this case, however, since the air gaps G are present only on the side of the p-channel MOS transistor Qₚ, the tensile side strain of the p-channel MOS transistor Qₚ is relaxed, so that the shear modulus of the sidewall insulating layers 9p′ is substantially decreased to make the strain of the p-channel region of the p-channel MOS transistor Qₚ on the compressive side which would enhance the hole mobility of the p-channel MOS transistor Qₚ. Furthermore, the SiGe layers 12S and 12D generate a compressive stress in the channel region of the p-channel MOS transistor Qₚ to enhance the hole mobility thereof. Thus, the characteristics such as the ON current of the p-channel MOS transistor Qₚ can be improved.

Further, even in FIG. 4J, the fringe capacitance of the p-channel MOS transistor Qₚ can be decreased by the air gaps G.

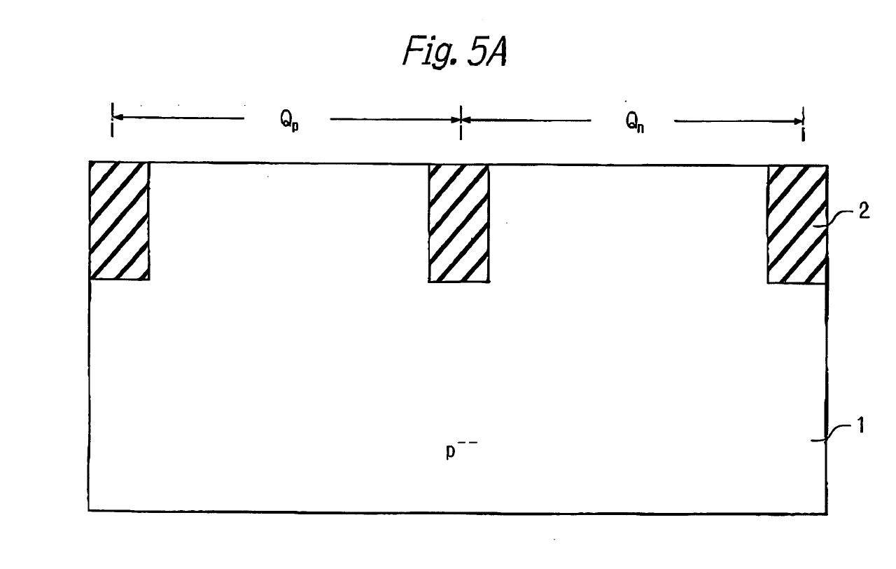

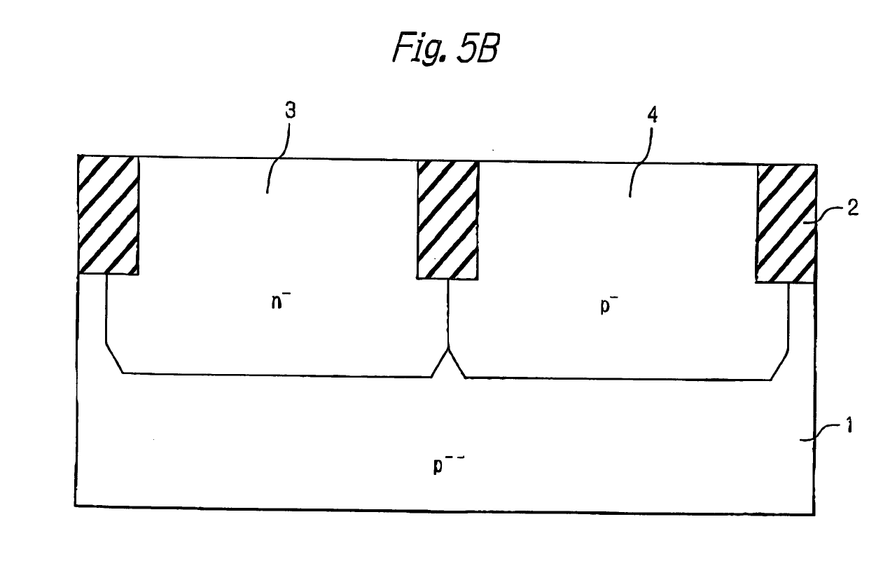

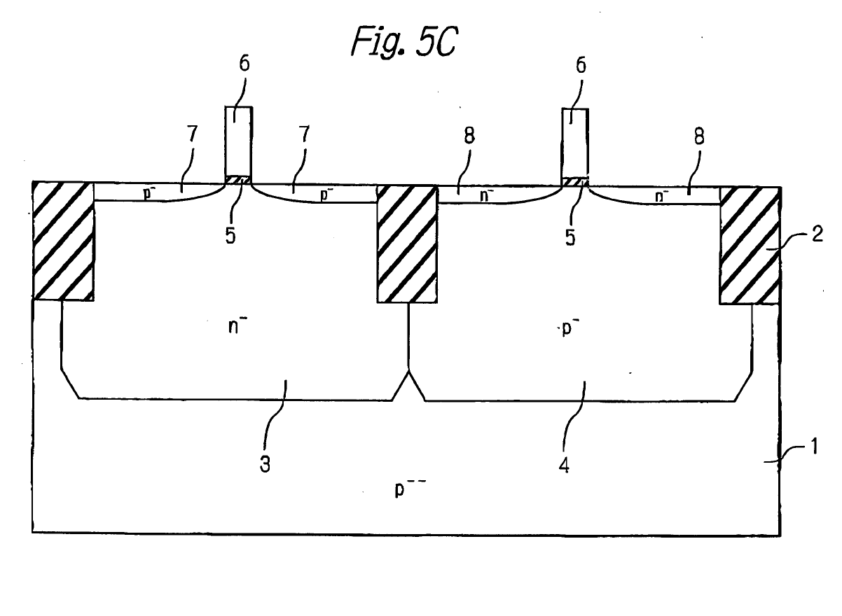

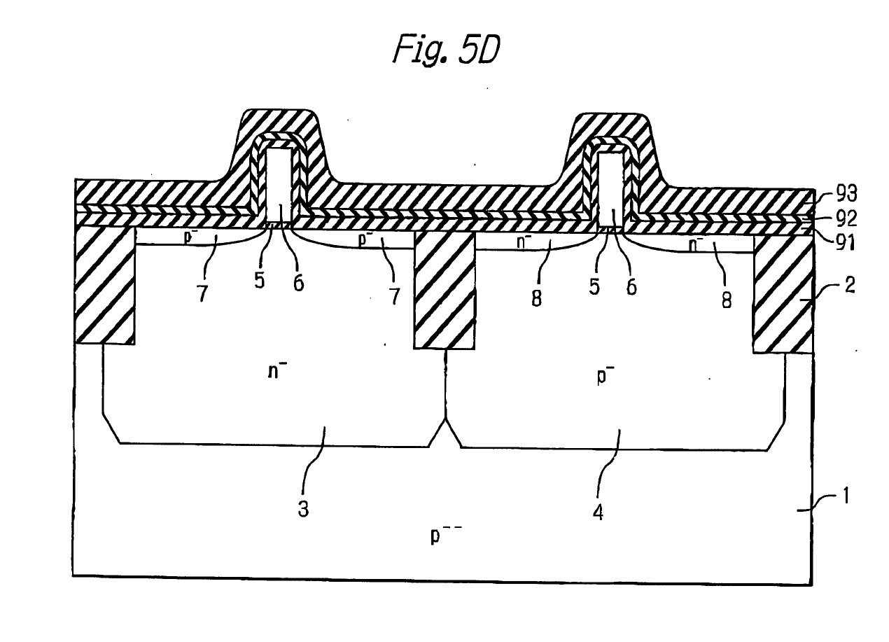

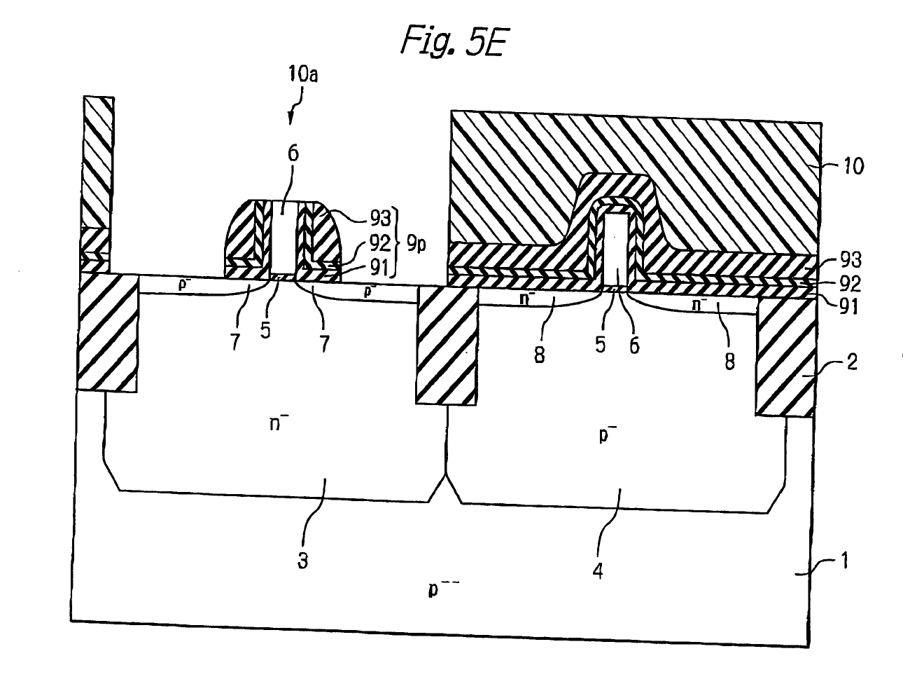

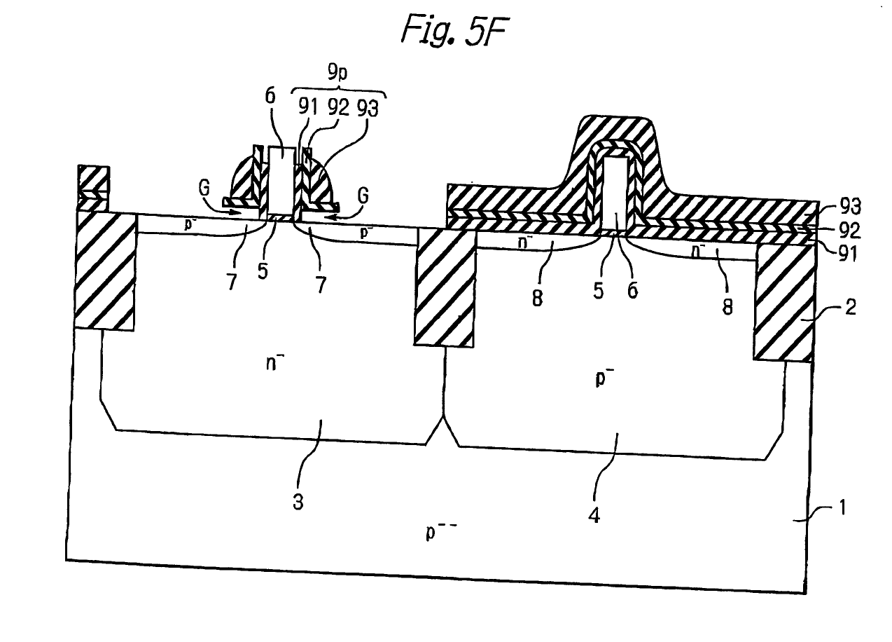

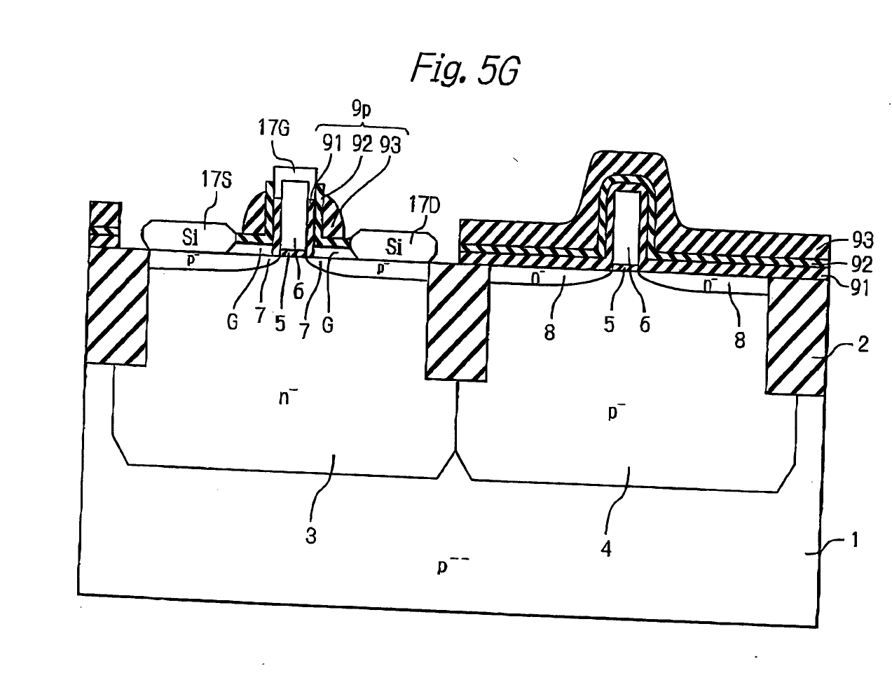

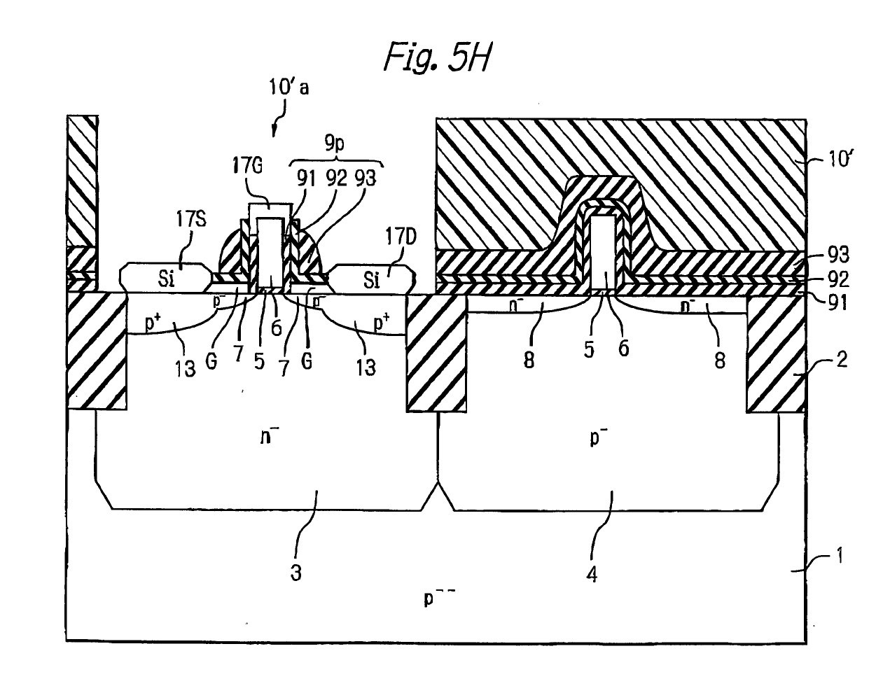

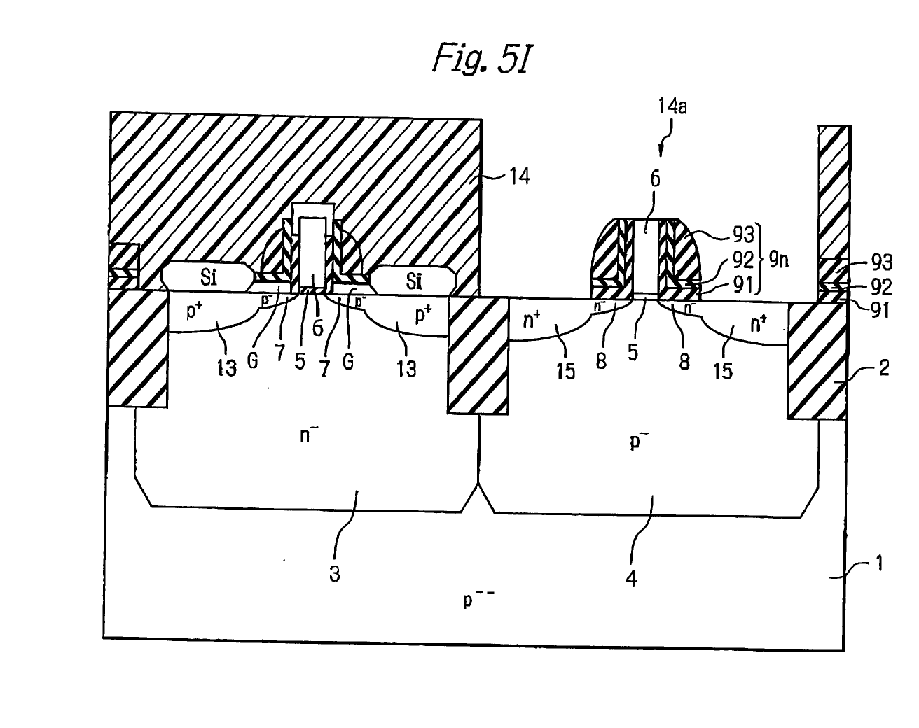

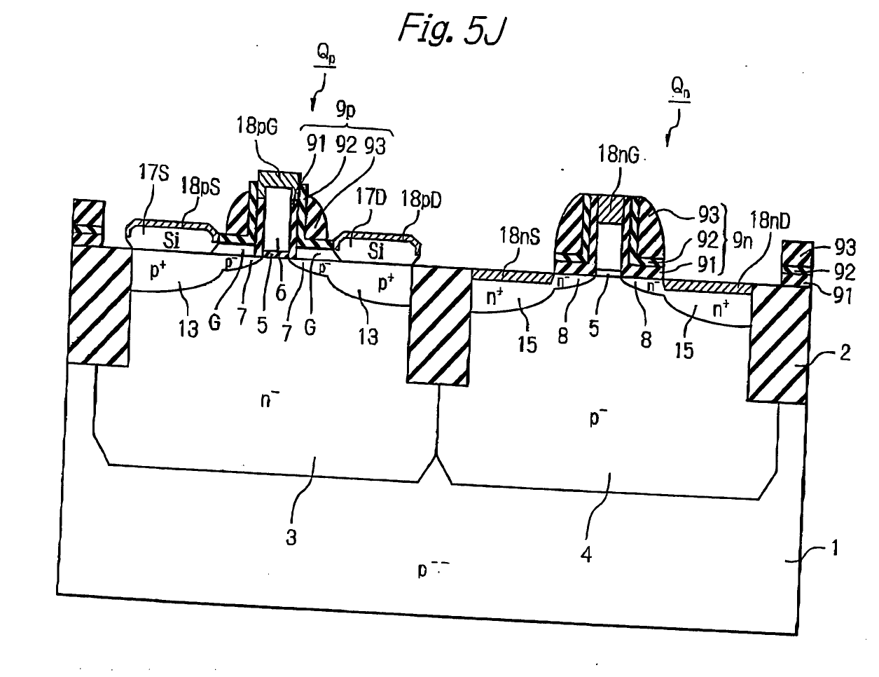

A third embodiment of the method for manufacturing a semiconductor device such as a p-channel MOS transistor Qₚ and an n-channel MOS transistor Qₙ according to the present invention will be explained next with reference to FIGS. 5A through 5J.

First, referring to FIG. 5A, in the same way as in FIG. 2A, an STI layer 2 is formed within a p⁻⁻-type monocrystalline silicon substrate 1 to partition areas for the transistors Qₚ and Qₙ from each other.

Next, referring to FIG. 5B, in the same way as in FIG. 2B, arsenic (or phosphorus) ions are implanted at a relatively-high energy into the silicon substrate 1 by using a photoresist pattern layer (not shown) having an opening corresponding to the p-channel MOS transistor Qₚ as a mask, to form an n⁻-type impurity diffusion well 3. Also, boron ions are implanted at a relatively-high energy into the silicon substrate 1 by using a photoresist pattern layer (not shown) having an opening corresponding to the n-channel MOS transistor Qₙ as a mask, to form a p⁻-type impurity diffusion well 4.

Next, referring to FIG. 5C, in the same way as in FIG. 2C, a gate insulating layer 5 made of silicon dioxide (SiO₂), silicon oxide nitride (SiON), or a high-k material such as HfO₂, HfSiO or HfAlO is formed. Then, a gate electrode layer 6 made of polycrystalline silicon is formed on the gate insulating layer 5. Then, the gate electrode layer 6 and the gate insulating layer 5 are patterned by a photolithography and etching process. Then, boron ions are implanted at a relatively-low energy into the n--type impurity diffusion well 3 by using a photoresist pattern layer (not shown) having an opening corresponding to the p-channel MOS transistor Qₚ as a mask in self-alignment with the gate electrode layer 6, to form p⁻-type impurity diffusion regions 7. Also, arsenic (or phosphorus) ions are implanted at a relatively-low energy into the p⁻-type impurity diffusion well 4 by using a photoresist pattern layer (not shown) having an opening corresponding to the n-channel MOS transistor Qₙ as a mask in self-alignment with the gate electrode layer 6, to form n⁻-type impurity diffusion regions 8.

Next, referring to FIG. 5D, in the same way as in FIG. 2D, in order to form sidewall insulating layers, a silicon dioxide layer 91, a silicon nitride layer 92 and a silicon dioxide layer 93 are sequentially deposited in this order on the entire surface by a CVD process.

Next, referring to FIG. 5E, a photoresist pattern layer 10 having an opening 10a corresponding to the p-channel MOS transistor Qₚ is formed by a photolithography process. Then, the silicon dioxide layer 93, the silicon nitride layer 92 and the silicon dioxide layer 91 are etched back by an anisotropic dry etching process, to form a sidewall insulating layer 9p. Then, the photoresist pattern layer 10 is removed.

Next, referring to FIG. 5F, in the same way as in FIG. 2F, the silicon dioxide layers 91 and 93 are etched by a wet etching process, so that air gaps G are formed between the silicon nitride layer 92 and the p⁻-type impurity diffusion regions 7.

Next, referring to FIG. 5G, Si layers 17G, 17S and 17D are epitaxially grown on the gate electrode layer 6, the source region and the drain region, respectively. In this case, the upper surfaces of the Si layers 17S and 17D are higher than those of the air gaps G. Also, it is preferable that the Si layers 17S and 17D are as close as possible to the sidewall insulating layer 9p. At best, the Si layers 17S and 17D are in contact with the sidewall insulating layer 9p, so that the air gaps G are clogged. Note that, since the epitaxial growth of Si layers is generally easier on monocrystalline silicon than on polycrystalline silicon, the Si layers 16S and 16D are thicker than the Si layer 16G.

Next, referring to FIG. 5H, in a similar way to those of FIG. 2H, a photoresist pattern layer 10′ having an opening 10′a corresponding to the p-channel MOS transistor Qₚ is formed by a photolithography process. Then, boron ions are implanted at a relatively-high energy into the n⁻-type impurity diffusion well 3 by using the photoresist pattern layer 10′ as a mask in self-alignment with the sidewall insulating layer 9p, to form p⁺-type impurity diffusion regions 11. Then, the photoresist pattern layer 10′ is removed.

Next, referring to FIG. 5I, in the same way as in FIG. 2I, a photoresist pattern layer 14 having an opening 14a corresponding to the n-channel MOS transistor Qₙ is formed by a photolithography process. Then, the silicon dioxide layer 93, the silicon nitride layer 92 and the silicon dioxide layer 91 are etched back by an anisotropic dry etching process, to form a sidewall insulating layer 9n. Then, arsenic (or phosphorus) ions are implanted at a relatively-high energy into the p⁻-type impurity diffusion well 4 by using the photoresist pattern layer 14 as a mask in self-alignment with the sidewall insulating layer 9n, to form n⁺-type impurity diffusion regions 15. Then, the photoresist pattern layer 14 is removed. Then, an annealing operation is performed upon the impurity diffusion regions 7, 8, 13 and 15.

Finally, referring to FIG. 5J, in a similar way to those of FIG. 2J, a metal layer (not shown) made of Ti, Pt, Co or Ni is deposited on the entire surface. In this case, since the upper surfaces of the Si layers 17S and 17D are above the air gaps G, the metal layer is not deposited within the air gaps G. Then, an annealing process is performed upon the metal layer and its underlying silicon component, so that silicide layers 18pG, 18pS, 18pD, 18nG, 18nS and 18nD made of TiSi₂, PtSi, CoSi₂ or NiSi are formed within the Si layer 17G, 17S, 17D, the gate electrode layer 6, the source region and the drain region of the n-channel MOS transistor Qₙ, respectively. Then, unreacted portions of the metal layer is removed by a wet etching process. That is, the silicide layers 18pG, 18pS, 18pD, 18nG, 18nS and 18nD are formed by a salicide process.

Thus, the p-channel MOS transistor Qₚ and the n-channel MOS transistor Qₙ are completed.

In FIG. 5J, since the Si layers 17S and 17D completely prevent the silicide layers 18pS and 18pD from extending into the impurity diffusion regions 7 and 13 beneath the air gaps G, the gain induced drain current and the junction leakage current can be suppressed.

Also, even in FIG. 5J, the sidewall insulating layers 9p for the p-channel MOS transistor Qₚ and the sidewall insulating layers 9n for the n-channel MOS transistor Qₙ have similar structures to each other. That is, the sidewall insulating layers 9p and 9n are of a three-layer structure formed by SiO₂/SiN/SiO₂ where the silicon nitride (SiN) layer 92 has an L-shaped cross-section. In this case, however, since the air gaps G are present only on the side of the p-channel MOS transistor Qₚ, the tensile side strain of the p-channel MOS transistor Qₚ is relaxed, so that the shear modulus of the sidewall insulating layers 9p is substantially decreased to make the strain of the p-channel region of the p-channel MOS transistor Qₚ on the compressive side which would enhance the hole mobility of the p-channel MOS transistor Qₚ. Thus, the characteristics such as the ON current of the p-channel MOS transistor Qₚ can be improved.

Further, even in FIG. 5J, the fringe capacitance of the p-channel MOS transistor Qₚ can be decreased by the air gaps G.

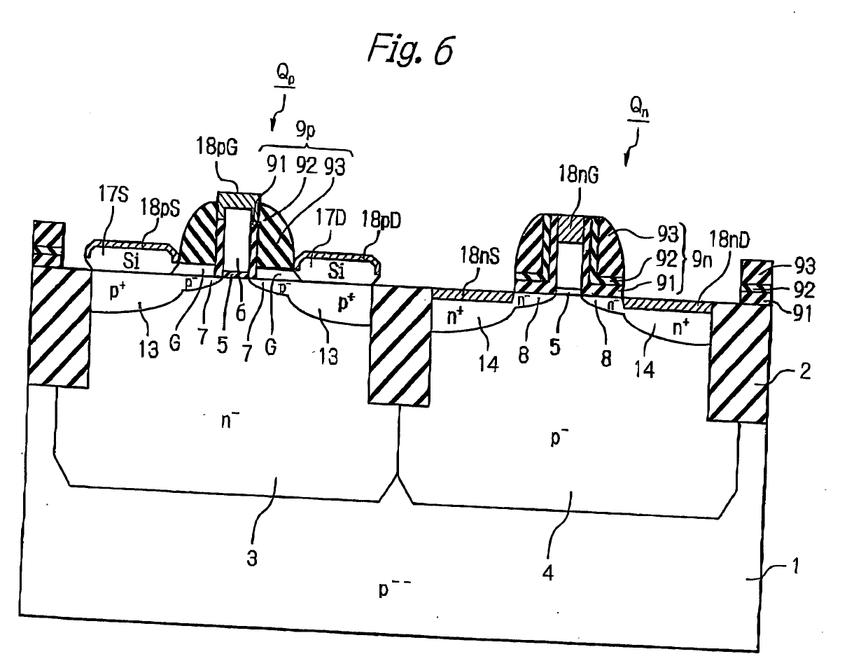

In the above-described third embodiment as illustrated in FIGS. 5A through 5J, although the sidewall insulating layers 9p and 9n are of a three-layer structure, two-layer structured sidewall insulating layers 9p′ and 9n′ can be adopted as illustrated in FIG. 6. In this case, the two-layer structured sidewall insulating layers 9p′ and 9n′ are formed by the processes as illustrated in FIGS. 4D, 4E and 4I.

In the above-described embodiments, STI layer 2 can be replaced by a field silicon dioxide layer formed by a LOCOS process. Also, if the n-channel MOS transistor Qₙ is not provided, the p-channel MOS transistor Qₚ can be formed in an n⁻-type monocrystalline silicon substrate. Further, the sidewall insulating layers 9p, 9n, 9p′ and 9n′ can be of a multilayer structure which includes at least one SiO₂ layer and at least one SiN layer.

1. A semiconductor device comprising:
a semiconductor substrate;
a gate insulating layer formed on said semiconductor substrate;
a gate electrode layer formed on said gate insulating layer;
a source region and a drain region formed within said semiconductor substrate adjacent to said gate electrode layer;
sidewall insulating layers formed on sidewalls of said gate electrode layer and said gate insulating layer, where air gaps are formed between one of said sidewall insulating layers and said source region and between another of the sidewall insulating layers and said drain region;
semiconductor layers formed on said source region and said drain region outside of said air gaps, upper surfaces of said semiconductor layers being higher than upper surfaces of said air gaps; and
silicide layers formed on said semiconductor layers.

2. The semiconductor device as set forth in claim 1, wherein each of said semiconductor layers comprises one of a SiGe layer and a Si layer.

3. The semiconductor device as set forth in claim 1, wherein said semiconductor layers are buried in recesses of said source region and said drain region, respectively, adjacent to said air gaps.

4. The semiconductor device as set forth in claim 1, wherein said semiconductor layers are in contact with respective ones of said sidewall insulating layers.

5. The semiconductor device as set forth in claim 1, wherein said sidewall insulating layers are of a multi-layer structure of SiO₂ and SiN.

6. The semiconductor device as set forth in claim 1, wherein said sidewall insulating layers are of a three-layer structure of SiO₂, SiN and SiO₂ where SiN has an L-shaped cross-section.

7. The semiconductor device as set forth in claim 1, wherein said sidewall insulating layers are of a two-layer structure of SiO₂ and SiN.

8. The semiconductor device as set forth in claim 1, being a p-channel MOS transistor.

9. A semiconductor device including a p-channel MOS transistor and an n-channel MOS transistor, wherein each of said p-channel MOS transistor and said n-channel MOS transistor comprises a gate insulating layer formed on a semiconductor substrate, a gate electrode layer formed on said gate insulating layer, a source region and a drain region formed within said semiconductor substrate adjacent to said gate electrode layer, and sidewall insulating layers of a multilayer structure of SiO₂ and SiN formed on sidewalls of said gate electrode layer and said gate insulating layer;
wherein air gaps are formed between one of said sidewall insulating layers and said source region of said p-channel MOS transistor and between another of said sidewall insulating layers and said drain region of said p-channel MOS transistor, and semiconductor layers are formed on said source region and said drain region of said p-channel MOS transistor outside of said air gaps, upper surfaces of said semiconductor layers being higher than upper surfaces of said air gaps; and
wherein silicide layers are formed on said semiconductor layers of said p-channel MOS transistor and said source region and said drain region of said n-channel MOS transistor.

10. The semiconductor device as set forth in claim 9, wherein said semiconductor layers are buried in recesses of said source region and said drain region of said p-channel MOS transistor adjacent to said air gaps.

11. A method for manufacturing a semiconductor device comprising;
forming a gate insulating layer on a semiconductor substrate;
forming a gate electrode layer on said gate insulating layer;
forming a source region and a drain region within said semiconductor substrate adjacent to said gate electrode layer;
forming sidewall insulating layers on sidewalls of said gate electrode layer and said gate insulating layer;
forming air gaps between one of said sidewall insulating layers and said source region and between another of the sidewall insulating layers and said drain region;
forming semiconductor layers on said source region and said drain region outside of said air gaps, upper surfaces of said semiconductor layers being higher than upper surfaces of said air gaps; and
forming silicide layers on said semiconductor layers.

12. The method as set forth in claim 11, wherein each of said semiconductor layers comprises one of a SiGe layer and a Si layer.

13. The method as set forth in claim 11, further comprising forming recesses in said source region and said drain region adjacent to said air gaps, before forming said semiconductor layers, so that said semiconductor layers are buried in said recesses of said source region and said drain region, respectively.

14. The method as set forth in claim 11, wherein said semiconductor layers are in contact with respective ones of said sidewall insulating layers.

15. The method as set forth in claim 11, wherein said sidewall insulating layers are of a multilayer structure of SiO₂ and SiN.

16. The method as set forth in claim 11, wherein said sidewall insulating layers are of a three-layer structure of SiO₂, SiN and SiO₂ where SiN has an L-shaped cross section.

17. The method as set forth in claim 11, wherein said sidewall insulating layers are of a two-layer structure of SiO₂ and SiN.

18. The method as set forth in claim 11, wherein said semiconductor device is a p-channel MOS transistor.

19. A method for manufacturing a semiconductor device including a p-channel MOS transistor and an n-channel MOS transistor, comprising;
forming first and second gate insulating layers on a semiconductor substrate for said p-channel MOS transistor and said n-channel MOS transistor, respectively;
forming first and second gate electrode layers on said first and second gate insulating layers;
forming a source region and a drain region of said p-channel MOS transistor within the semiconductor substrate adjacent to said first gate electrode layer and a source region and a drain region of said p-channel MOS transistor within said semiconductor substrate adjacent to said second gate electrode layer; and
forming first sidewall insulating layers of a multi-layer structure of SiO₂ and SiN on sidewalls of said first gate electrode layer and said first gate insulating layer, and second sidewall insulating layers of said multi-layer structure of SiO₂ and SiN on sidewalls of said second gate electrode layer and said second gate insulating layer;
forming air gaps between one of said first sidewall insulating layers and said source region of said p-channel MOS transistor and between another of said first sidewall insulating layers and said drain region of said p-channel MOS transistor;
forming semiconductor layers on said source region and said drain region of said p-channel MOS transistor outside of said air gaps, upper surfaces of said semiconductor layers being higher than upper surfaces of said air gaps; and
forming silicide layers on said semiconductor layers of said p-channel MOS transistor and said source region and said drain region of said n-channel MOS transistor.

20. The method as set forth in claim 19, further comprising forming recesses of said source region and said drain region of said p-channel MOS transistor adjacent to said air gaps before forming said semiconductor layers, so that said semiconductor layers are buried in said recesses.
